(19) United States
(12) Patent Application Publication
(10) Pub. No.: US 2025/0246501 A1
(43) Pub. Date: Jul. 31, 2025

(54) INTEGRATED CIRCUIT ASSEMBLY WITH DIE COUPLED TO LID

(71) Applicant: Apple Inc., Cupertino, CA (US)

(72) Inventors: Murali Krishna Atluru, Liberty Hill, TX (US); Cheng P. Tan, Fremont, CA (US)

(21) Appl. No.: 18/423,003

(22) Filed: Jan. 25, 2024

(51) Int. Cl. H01L 23/367; H01L 23/00; H01L 25/18; H10B 80/00

(52) U.S. Cl. CPC H01L 23/3675; H01L 24/05; H01L 24/32; H01L 24/83; H01L 25/18; H10B 80/00; H01L 24/16; H01L 24/73; H01L 2224/05624; H01L 2224/05647; H01L 2224/16225; H01L 2224/32013; H01L 2224/32245; H01L 2224/73253; H01L 2224/83815; H01L 2924/1436

(57) ABSTRACT

An integrated circuit assembly includes a semiconductor die, a copper coating disposed on a surface of the semiconductor die, a solder bond layer disposed on the copper coating, and a copper lid disposed on the solder bond layer.

### BACKGROUND

The present disclosure generally relates to integrated circuit assemblies. More particularly, the present disclosure relates to coupling a lid of an integrated circuitry assembly with a die of the integrated circuit assembly.

In mobile devices and other consumer electronics, thermal management is an important design factor. In particular, components associated with data processing (e.g., a system-on-chip or SoC) may produce relatively high levels of thermal output. While traditional configurations employ various techniques for dissipating heat from such components, traditional configurations may be relatively large (e.g., thick), expensive, and/or ineffective in dissipating heat. Additionally or alternatively, traditional configurations may include undesirable structural characteristics (e.g., too rigid, too flexible, etc.).

### SUMMARY

In one embodiment, an integrated circuit assembly includes a semiconductor die, a copper coating disposed on a surface of the semiconductor die, a solder bond layer disposed on the copper coating, and a copper lid disposed on the solder bond layer.

In another embodiment, an integrated circuit assembly includes a semiconductor die, a thermally conductive coating disposed on a surface of the semiconductor die, a solder bond layer disposed on the thermally conductive coating, and a lid disposed on the solder bond layer.

In another embodiment, a method for manufacturing an integrated circuit assembly includes disposing a thermally conductive coating on a surface of a semiconductor die of the integrated circuit assembly. The method also includes soldering the thermally conductive coating to a lid of the integrated circuit assembly via a solder bond layer.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts:

FIG. 1 is a block diagram of an electronic device, in accordance with an embodiment of the present disclosure;

FIG. 2 is a perspective view of the electronic device of FIG. 1 in the form of a notebook computer, in accordance with an embodiment of the present disclosure;

FIG. 3 is a front view of the electronic device of FIG. 1 in the form of a handheld device, in accordance with an embodiment of the present disclosure;

FIG. 4 is a front view of the electronic device of FIG. 1 in the form of portable tablet computer, in accordance with an embodiment of the present disclosure;

FIG. 5 is a front view of the electronic device of FIG. 1 in the form of a desktop computer, in accordance with an embodiment of the present disclosure;

FIG. 6 is a front and side view of the electronic device of FIG. 1 in the form of a wearable electronic device, in accordance with an embodiment of the present disclosure;

FIG. 7 is a cross-sectional front view of an integrated circuit assembly including a die (e.g., semiconductor die), a lid (e.g., of an enclosure), and a solder bond layer coupling the die to the lid, in accordance with an embodiment of the present disclosure;

FIG. 8 is a cross-sectional front view of an integrated circuit assembly including a die (e.g., semiconductor die), a lid (e.g., of an enclosure) having a perforated area, and a solder bond layer coupling the die to the perforated area of the lid, in accordance with an embodiment of the present disclosure;

FIG. 9 is a cross-sectional front view of an integrated circuit assembly including a die (e.g., semiconductor die), a lid (e.g., of an enclosure), and a solder bond layer coupling the die to the lid, where perforations extend through the lid and the solder bond layer, in accordance with an embodiment of the present disclosure;

FIG. 10 is a cross-sectional front view of a die (e.g., semiconductor die) of an integrated circuit assembly and a thermally conductive coating (e.g., copper coating) disposed on a surface and/or forming a part of the die, in accordance with an embodiment of the present disclosure;

FIG. 11 is a perspective view of a perforated area of a lid of an integrated circuit assembly, where the perforated area includes perforations that are uniform in size and shape, in accordance with an embodiment of the present disclosure;

FIG. 12 is a perspective view of a perforated area of a lid of an integrated circuit assembly, where the perforated area includes at least one perforation that differs in size and/or shape from at least one other perforation, in accordance with an embodiment of the present disclosure; and

FIG. 13 is a process flow diagram of a method of manufacturing or assembling at least a portion of an integrated circuit assembly, including a die (e.g., semiconductor die) coupled to a lid (e.g., of an enclosure) via a solder bond layer, in accordance with an embodiment of the present disclosure.

### DETAILED DESCRIPTION OF SPECIFIC EMBODIMENTS

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on.

The present disclosure is directed to integrated circuit assemblies. More specifically, the present disclosure relates to a solder bond layer coupling a lid of an integrated circuitry assembly to a thermally conductive coating disposed on a surface of a die of the integrated circuit assembly.

Integrated circuit assemblies may include a semiconductor die with heat generating componentry disposed therein or thereon, such as processing circuitry, memory circuitry (e.g., dynamic random-access memory or DRAM), and the like. Dissipating the heat generated by these components is important to ensure operational integrity of the integrated circuit assembly and/or a an electronic device, such as a mobile phone, computer, or other consumer electronics, associated with the integrated circuit assembly. In traditional configurations, thermal management features may be relatively large (e.g., thick), expensive, and/or ineffective. Additionally or alternatively, traditional configurations may include thermal management features at the cost of various desirable structural characteristics (e.g., a particular rigidity, a particular flexibility, etc.).

In accordance with the present disclosure, a heat transfer path of an integrated circuit assembly includes a semiconductor die, a lid (e.g., of an enclosure) disposed over the semiconductor die, and a solder bond layer coupling the lid to a thermally conductive coating disposed on a surface of the semiconductor die. The thermally conductive coating, the solder bond layer, and the lid may include materials with relatively high thermal conductivity. For example, the thermally conductive coating and the lid may include copper, aluminum, or some other material having a thermal conductivity greater than 10 Watts per Meter-Kelvin (W/m-K). In some embodiments, the thermally conductive coating and/or the lid may include a material having a thermal conductivity greater than 200 Watts per Meter-Kelvin (W/m-K). Additionally or alternatively, the solder bond layer may include a soldering material (e.g., a metal alloy soldering material) having a thermal conductivity greater than 10 W/m-K. In some embodiments, the soldering bond layer may include a soldering material having a thermal conductivity greater than 80 W/m-K. These relatively high thermal conductivities, along with other features of the present disclosure, may improve a heat transfer path between the semiconductor die and the lid.

The soldering material may include a melting temperature (e.g., 200-350 degrees Celsius) lower than that of the lid and the thermally conductive coating disposed on the semiconductor die. In this way, the soldering material may be employed in a soldering process to form the solder bond layer coupling the thermally conductive coating disposed on the surface of the semiconductor die to the lid. For example, the soldering material may be disposed between the thermally conductive coating and the lid, and the assembly may be heated at or slightly above the melting temperature of the soldering material, which heats the thermally conductive coating and the lid and melts the soldering material. As the assembly cools, the solder bond material may harden into the solder bond layer coupling the thermally conductive coating to the lid.

In some embodiments, the solder bond layer couples the thermally conductive coating disposed on the surface of the semiconductor die with a perforated area of the lid. Further, in some embodiments, perforations (e.g., holes) are disposed through both the perforated area of the lid and the solder bond layer (e.g., after the lid is coupled, via the solder bond layer, to the thermally conductive coating disposed on the surface of the semiconductor die). Such perforations in the perforated area of the lid and/or in the solder bond layer are configured to enable a controlled swelling of the semiconductor die as heat is generated by componentry (e.g., processing circuitry, DRAM, etc.) disposed in or on the semiconductor die. In this way, the heat transfer path from the semiconductor die to the lid enables desirable heat dissipation and reduces or negates undesirable compression of the semiconductor die. These and other aspects of the present disclosure are described in detail below with reference to the drawings.

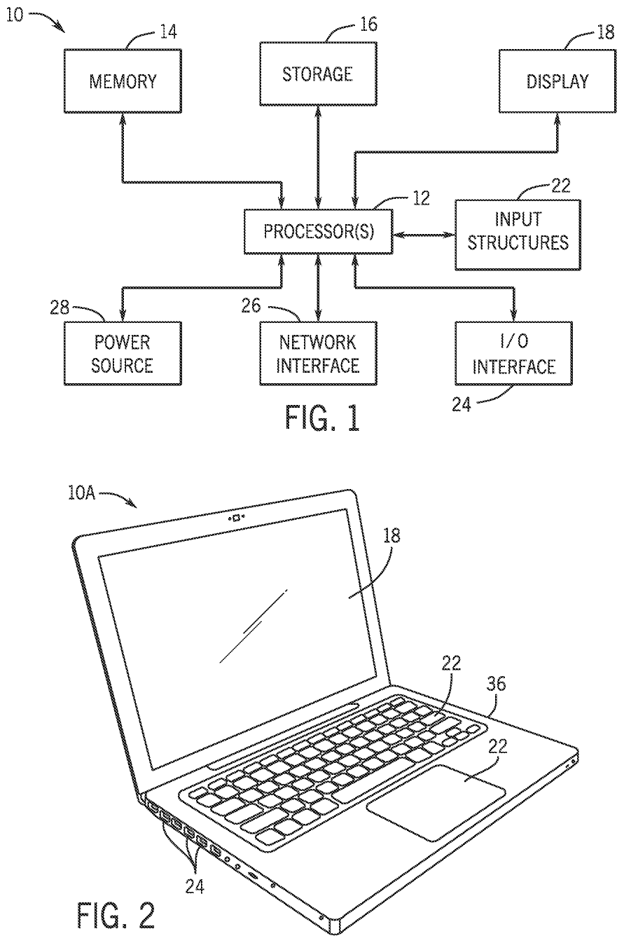

With the foregoing in mind, a general description of suitable electronic devices that may employ switching mixed topology regulators in their circuitry will be provided below. Turning first to FIG. 1, an electronic device 10 according to an embodiment of the present disclosure may include, among other things, one or more processor(s) 12, memory 14, nonvolatile storage 16, a display 18, input structures 22, an input/output (I/O) interface 24, a network interface 26, and a power source 28. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in electronic device 10.

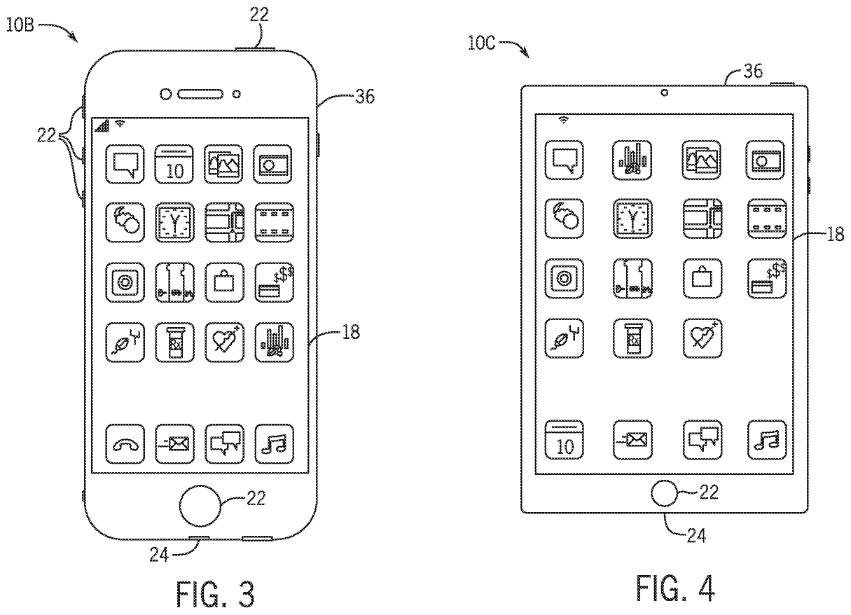

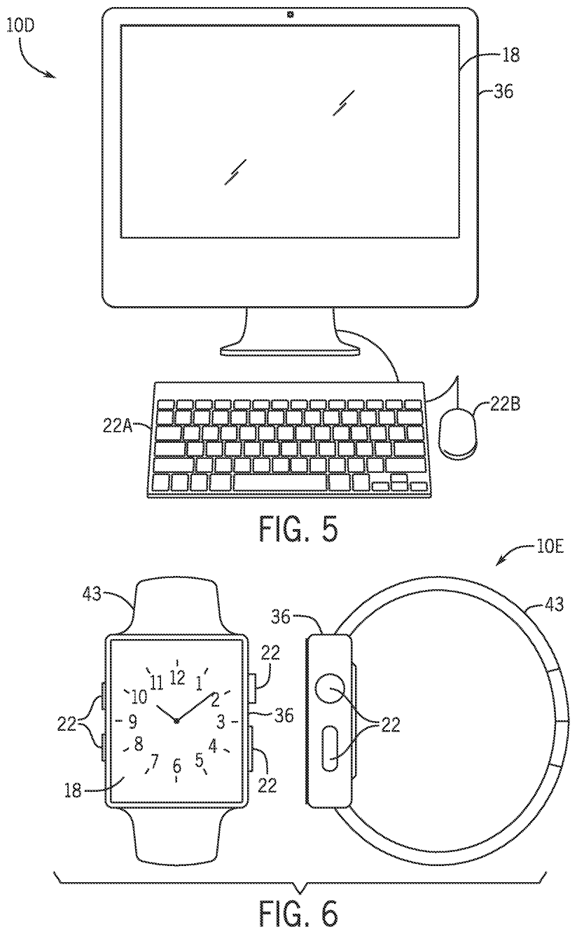

By way of example, the electronic device 10 may represent a block diagram of the notebook computer depicted in FIG. 2, the handheld device depicted in FIG. 3, the handheld device depicted in FIG. 4, the desktop computer depicted in FIG. 5, the wearable electronic device depicted in FIG. 6, or similar devices. It should be noted that the processor(s) 12 and other related items in FIG. 1 may be generally referred to herein as “data processing circuitry.” Such data processing circuitry may be embodied wholly or in part as software, firmware, hardware, or any combination thereof. Furthermore, the data processing circuitry may be a single contained processing module or may be incorporated wholly or partially within any of the other elements within the electronic device 10.

In the electronic device 10 of FIG. 1, the processor(s) 12 may be operably coupled with the memory 14 and the nonvolatile storage 16 to perform various algorithms. Such programs or instructions executed by the processor(s) 12 may be stored in any suitable article of manufacture that includes one or more tangible, computer-readable media at least collectively storing the instructions or routines, such as the memory 14 and the nonvolatile storage 16. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor(s) 12 to enable the electronic device 10 to provide various functionalities.

In certain embodiments, the display 18 may be a liquid crystal display (LCD), which may allow users to view images generated on the electronic device 10. In some embodiments, the display 18 may include a touch screen, which may allow users to interact with a user interface of the electronic device 10. Furthermore, it should be appreciated that, in some embodiments, the display 18 may include one or more organic light emitting diode (OLED) displays, or some combination of LCD panels and OLED panels.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. The network interface 26 may include, for example, one or more interfaces for a personal area network (PAN), such as a Bluetooth network, for a local area network (LAN) or wireless local area network (WLAN), such as an 802.11x Wi-Fi network, and/or for a wide area network (WAN), such as a 3rd generation (3G) cellular network, 4th generation (4G) cellular network, Long-Term Evolution (LTE) cellular network, Long-Term Evolution license assisted access (LTE-LAA) cellular network, 5th generation (5G) cellular network, or New Radio (NR) cellular network. The network interface 26 may also include one or more interfaces for, for example, broadband fixed wireless access networks (WiMAX), mobile broadband Wireless networks (mobile WiMAX), asynchronous digital subscriber lines (e.g., ADSL, VDSL), digital video broadcasting-terrestrial (DVB-T) and its extension DVB Handheld (DVB-H), ultra-wideband (UWB), alternating current (AC) power lines, and so forth. Network interfaces 26 such as the one described above may benefit from the use of tuning circuitry, impedance matching circuitry and/or noise filtering circuits that may include polymer capacitors such as the ones described herein. As further illustrated, the electronic device 10 may include a power source 28. The power source 28 may include any suitable source of power, such as a rechargeable lithium polymer (Li-poly) battery and/or an alternating current (AC) power converter.

In certain embodiments, the electronic device 10 may take the form of a computer, a portable electronic device, a wearable electronic device, or other type of electronic device. Such computers may include computers that are generally portable (such as laptop, notebook, and tablet computers) as well as computers that are generally used in one place (such as conventional desktop computers, workstations, and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of a notebook computer 10A, is illustrated in FIG. 2 in accordance with one embodiment of the present disclosure. The depicted computer 10A may include a housing or enclosure 36, a display 18, input structures 22, and ports of an I/O interface 24. In one embodiment, the input structures 22 (such as a keyboard and/or touchpad) may be used to interact with the computer 10A, such as to start, control, or operate a GUI or applications running on computer 10A. For example, a keyboard and/or touchpad may allow a user to navigate a user interface or application interface displayed on display 18.

FIG. 3 depicts a front view of a handheld device 10B, which represents one embodiment of the electronic device 10. The handheld device 10B may represent, for example, a portable phone, a media player, a personal data organizer, a handheld game platform, or any combination of such devices. By way of example, the handheld device 10B may be a model of an iPod® or iPhone® available from Apple Inc. of Cupertino, California. The handheld device 10B may include an enclosure 36 to protect interior components from physical damage and to shield them from electromagnetic interference. The enclosure 36 may surround the display 18. The I/O interfaces 24 may open through the enclosure 36 and may include, for example, an I/O port for a hard-wired connection for charging and/or content manipulation using a standard connector and protocol, such as the Lightning connector provided by Apple Inc., a universal serial bus (USB), or other similar connector and protocol.

User input structures 22, in combination with the display 18, may allow a user to control the handheld device 10B. For example, the input structures 22 may activate or deactivate the handheld device 10B, navigate user interface to a home screen, a user-configurable application screen, and/or activate a voice-recognition feature of the handheld device 10B. Other input structures 22 may provide volume control, or may toggle between vibrate and ring modes. The input structures 22 may also include a microphone may obtain a user's voice for various voice-related features, and a speaker may enable audio playback and/or certain phone capabilities. The input structures 22 may also include a headphone input may provide a connection to external speakers and/or headphones.

FIG. 4 depicts a front view of another handheld device 10C, which represents another embodiment of the electronic device 10. The handheld device 10C may represent, for example, a tablet computer, or one of various portable computing devices. By way of example, the handheld device 10C may be a tablet-sized embodiment of the electronic device 10, which may be, for example, a model of an iPad® available from Apple Inc. of Cupertino, California.

Turning to FIG. 5, a computer 10D may represent another embodiment of the electronic device 10 of FIG. 1. The computer 10D may be any computer, such as a desktop computer, a server, or a notebook computer, but may also be a standalone media player or video gaming machine. By way of example, the computer 10D may be an iMac®, a MacBook®, or other similar device by Apple Inc. It should be noted that the computer 10D may also represent a personal computer (PC) by another manufacturer. A similar enclosure 36 may be provided to protect and enclose internal components of the computer 10D such as the display 18. In certain embodiments, a user of the computer 10D may interact with the computer 10D using various peripheral input devices, such as the keyboard 22A or mouse 22B (e.g., input structures 22), which may connect to the computer 10D.

Similarly, FIG. 6 depicts a wearable electronic device 10E representing another embodiment of the electronic device 10 of FIG. 1 that may be configured to operate using the techniques described herein. By way of example, the wearable electronic device 10E, which may include a wristband 43, may be an Apple Watch® by Apple, Inc. However, in other embodiments, the wearable electronic device 10E may include any wearable electronic device such as, for example, a wearable exercise monitoring device (e.g., pedometer, accelerometer, heart rate monitor), or other device by another manufacturer. The display 18 of the wearable electronic device 10E may include a touch screen display 18 (e.g., LCD, OLED display, active-matrix organic light emitting diode (AMOLED) display, and so forth), as well as input structures 22, which may allow users to interact with a user interface of the wearable electronic device 10E.

The electronic device 10 may have one or more components to be operated with varying levels of voltage. As such, the electronic device 10 may include a switching regulator located on a die to facilitate conversion of an input direct-current (DC) voltage to a desired output DC voltage. As discussed above, implementing a switching regulator with one or more power stages disposed externally of a main package of the switching regulator may allow for heat generated within the main package to be dissipated externally of the main package.

Any of the devices 10 illustrated in FIGS. 1-6 may employ an integrated circuit assembly, such as the processor(s) 12 in FIG. 1, that includes a lid (e.g., of an enclosure), a die (e.g., a semiconductor die), and a solder bond layer coupling the lid to a thermally conductive coating disposed on a surface the die. The lid, the solder bond layer, and/or the thermally conductive coating may include materials with relatively high thermal conductivity. In this way, the copper layer and the solder bond layer may establish a heat transfer path from the die to the lid. Further, other aspects of the integrated circuit assembly, such as perforations through the lid and/or the solder bond layer, may enable controlled swelling of the die without substantially reducing heat transfer from the die to the lid. These and other aspects of the present disclosure are described in detail below with reference to later drawings.

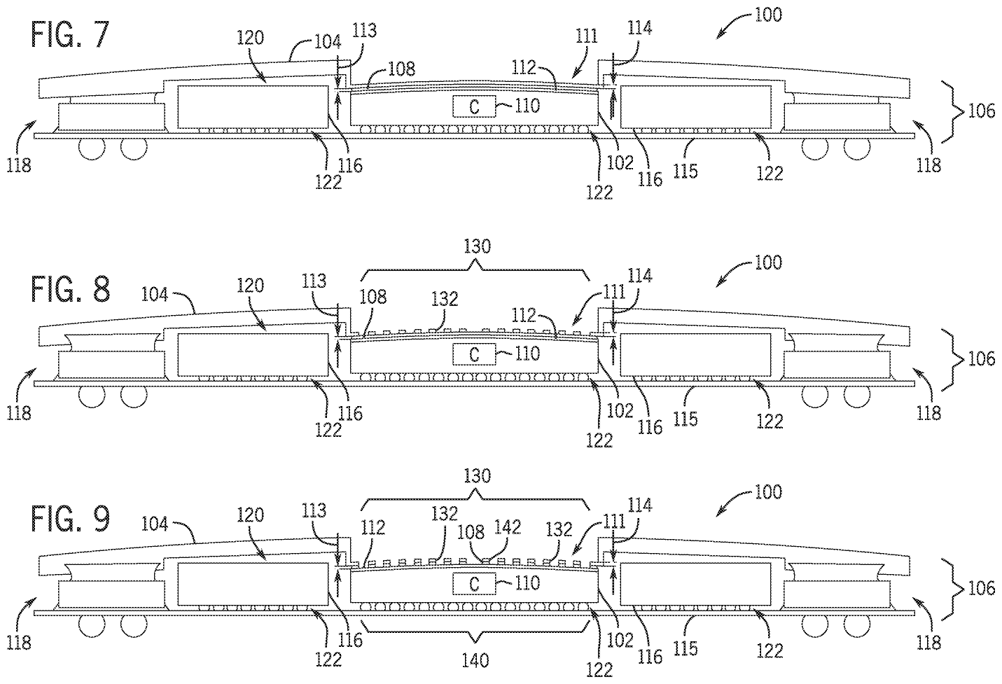

With the foregoing in mind, FIG. 7 is a cross-sectional front view of an embodiment of an integrated circuit assembly 100 including a die 102 (e.g., semiconductor die), a lid 104 (e.g., of an enclosure 106) disposed over the die 102, and a solder bond layer 108 coupling a portion of the die 102 to a portion of the lid 104. As shown, the die 102 in FIG. 7 includes circuitry 110 (e.g., processing circuitry and/or memory circuitry) disposed thereon, therein, or otherwise integrated with the die 102. The solder bond layer 108 is configured to couple the lid 104, such as a recessed portion 111 of the lid 104, to a thermally conductive coating 112 (e.g., thermally conductive layer) disposed on a surface of the die 102. In some embodiments, the thermally conductive coating 112 is considered a part of the die 102. As described in detail below, the thermally conductive coating 112 and the solder bond layer 108 are configured to establish a heat transfer path from the die 102 to the lid 104, such that heat generated by the circuitry 110 of the die 102 is dissipated from the die 102 to the lid 104. Indeed, dissipating the heat from the die 102 enables desirable functionality, performance, and/or longevity of the integrated circuit assembly 100. In some embodiments, a thermal management module may be coupled to the lid 104 and configured to further dissipate the heat from the integrated circuit assembly 100 (e.g., to environment).

In accordance with the present disclosure, heat transfer from the die 102 to the lid 104 may be improved via the thermally conductive coating 112 and the solder bond layer 108, and by employing certain materials in the thermally conductive coating 112, the solder bond layer 108, and/or the lid 104. For example, the thermally conductive coating 112 and the lid 104 may include materials, such as copper, aluminum, and/or certain oxides, having a thermal conductivity greater than 10 Watts per Meter-Kelvin (W/m-K) (e.g., 10-450 W/m-K, 100-400 W/m-K, or 200-300 W/m-K). Further, the solder bond layer 108 may include a material, such as certain metal alloys, having a thermal conductivity greater than 10 W/m-K (e.g., 10-350 W/m-K, 50-250 W/m-K, or 100-150 W/m-K). In some embodiments, the materials of the thermally conductive coating 112 and/or the material of the solder bond layer 108 are thermally conductive, as outlined above, and electrically conductive, thereby improving and/or enabling a self-shielding capability or function of the die 102. One such non-limiting embodiment is illustrated in, and described in greater detail with respect to, FIG. 9. Use of the solder bond layer 108 to couple the thermally conductive coating 112 of the die 102 to the lid 104, along with the relatively high thermal conductivities of the thermally conductive coating 112, the solder bond layer 108, and the lid 104, may improve heat transfer from the die 102 to the lid 104 relative to traditional configurations.

Further, the material selected for the solder bond layer 108 may include a melting temperature that is lower than that of the thermally conductive coating 112 and the lid 104. As an example, the melting temperature of the material(s) employed for the solder bond layer 108 may be between 200 degrees Celsius and 350 degrees Celsius, whereas a melting temperature of the material(s) employed in the thermally conductive coating 112 and the lid 104, such as copper, aluminum, and/or certain oxides, is significantly higher. Accordingly, the soldering material with the relatively low melting temperature may be disposed between the lid 104 and the thermally conductive coating 112 of the die 102, melted, and then allowed to cool and solidify into the solder bond layer 108 coupling the thermally conductive coating 112 and the lid 104. Upon cooling, the solder bond layer 108 may include a thickness 113 between 10 microns and 100 microns, 30 microns to 80 microns, or 50 microns to 60 microns. In certain embodiments, the thickness 113 of the solder bond layer 108 may be relatively small compared to a thickness 114 of the portion of the lid 104 (e.g., the recessed portion 111 of the lid 104) contacting the solder bond layer 108. For example, the thickness 114 may be between 30 microns and 350 microns, 90 microns to 300 microns, or 150 microns to 250 microns.

Employing the solder bond layer 108 as outlined above may establish a structural coupling between the lid 104 and the thermally conductive coating 112 of the die 102, where the structural coupling improves heat transfer from the die 102 to the lid 104 and strikes a desirable balance between rigidity and flexibility of the integrated circuit assembly 100. In this way, presently disclosed embodiments improve heat transfer from the die 102 to the lid 104, and improve structural characteristics of the integrated circuit assembly 100, as described in greater detail with reference to later drawings.

The embodiment illustrated in FIG. 7 also includes a substrate 115, one or more segments of dynamic random-access memory (DRAM) 116, and one or more stiffener assemblies 118. The stiffener assemblies 118 may couple the substrate 115 to the lid 104 such that the stiffener assemblies 118, the substrate 115, and the lid 104 at least partially form the enclosure 106. In this way, the enclosure 106 in FIG. 7 defines a cavity 120 in which the die 102 (including the thermally conductive coating 112), the solder bond layer 108, and the one or more DRAM 116 are disposed. As shown, welding beads 122 may be employed to couple the die 102 and the DRAM 116 to the substrate 115.

In certain embodiments, certain additional aspects of the lid 104 are configured to improve structural characteristics of the integrated circuit assembly 100. For example, FIG. 8 is a cross-sectional front view of an embodiment of the integrated circuit assembly 100 including the die 102, the thermally conductive coating 112 of the die 102, the solder bond layer 108, and the lid 104 (e.g., of the enclosure 106), where the lid 104 includes a perforated area 130 having a number of perforations 132 (e.g., holes, openings) extending therethrough. As shown, the perforated area 130 may be disposed in the recessed portion 111 of the lid 104 in certain embodiments, such that the perforated area 130 is spatially aligned with the solder bond layer 108, the thermally conductive coating 112, and the circuitry 110 of the die 102. The perforations 132 may extend through an entirety of the thickness 114 of the lid 104 in the perforated area 130 of the lid 104. In this way, the solder bond layer 108 may be exposed through the perforations 132 in the perforated area 130 of the lid 104. It should be noted that the perforations 132 may be disposed through the perforated area 130 of the lid 104 before or after the lid 104 is coupled to the thermally conductive coating 112 of the die 102 via the solder bond layer 108.

As heat is generated via the circuitry 110 in the die 102 during operation of the integrated circuit assembly 100, the die 102 may begin to swell (e.g., thermally expand). Some swelling of the die 102 may be permitted to enable desirable functionality, performance, and/or longevity of the integrated circuit assembly 100, and to avoid an undesirably large amount of compression against the die 102 as it swells within a permittable range. For example, the perforations 132 in the perforated area 130 of the lid 104 may be tuned to permit a desirable amount of swelling in the die 102 and to avoid undesirable compression against the die 102 as it swells. Geometries and/or sizes of the perforations 132 may be uniform or non-uniform based on various characteristics associated with the integrated circuit assembly 100. As an example of non-uniform geometries and/or sizes, one or more of the perforations 132 may be relatively large (e.g., larger than one or more other of the perforations 132) in a portion of the perforated area 130 that is spatially aligned with (e.g., extending over) a known hot spot associated with heat generated by the circuitry 110 of the die 102. More detailed aspects of the perforations 132 in the perforated area 130 of the lid 104 are illustrated in, and described with respect to, later drawings.

In some embodiments, additional perforations may be disposed through the solder bond layer 108 of the integrated circuit assembly 100. For example, FIG. 9 is a cross-sectional front view of an embodiment of the integrated circuit assembly 100 including the die 102, the thermally conductive coating 112 of the die 102, the solder bond layer 108, and the lid 104 (e.g., of the enclosure 106), where the solder bond layer 108 includes an additional perforated area 140 having additional perforations 142. The additional perforations 142 of the additional perforated area 140 of the solder bond layer 108 may be spatially aligned with the perforations 132 of the perforated area 130 of the lid 104. In certain embodiments employing the additional perforations 142 in the additional perforated area 140 of the solder bond layer 108, such as embodiments in which the additional perforations 142 are relatively large, the solder bond layer 108 and/or the thermally conductive coating 112 may include thermally and electrically conductive materials configured to maintain or improve a self-shielding capability or function of the die 102. In general, the additional perforations 142 in the additional perforated area 140 of the solder bond layer 108 may contribute to and/or improve the structural characteristics (e.g., enabling permittable swelling of the die 102 and/or precluding undesirable compression against the die 102 as it swells) described above with respect to the embodiment illustrated in FIG. 8.

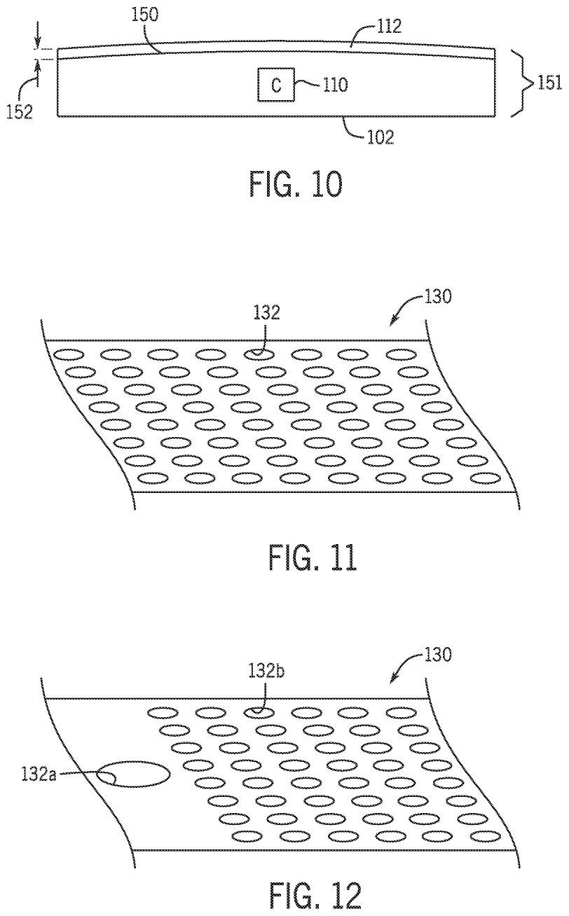

FIG. 10 is a cross-sectional front view of an embodiment of the die 102 that may be employed in an integrated circuit assembly. As shown, the die 102 includes a surface 150 of a body 151 of the die 102, and the thermally conductive coating 112 (e.g., copper coating) disposed on the surface 150 of the body 151. The thermally conductive coating 112 may be disposed on the surface 150 via a thin film or vapor deposition technique such that the thermally conductive coating 112 includes a thickness 152 between 10 nanometers and 10 microns.

FIGS. 11 and 12 are perspective views of embodiments of the perforated area 130 of a lid of an integrated circuit assembly. In FIG. 11, the perforations 132 of the perforated area 130 include uniform sizes and shapes. The embodiment illustrated in FIG. 11 is merely an example. It should be understood that the perforations 132 may include other sizes and/or shapes (e.g., ovals, ellipses, squares, rectangles, triangles, etc.) in other embodiments.

In FIG. 12, a first perforation 132a of the perforated area 130 is larger than second perforations 132b of the perforated area 130. The perforated area 130 may be located in an integrated circuit assembly such that the first perforation 132a is spatially aligned with (e.g., extending over) a hot spot associated with heat generated by circuitry (e.g., processing circuitry, memory circuitry) of a die, thereby enabling additional swelling of the die at or adjacent to the hot spot. The hot spot may be identified based on experimentation and the various perforations 132a, 132b may be tuned (e.g., sized, shaped, and/or located) based on the results of the experimentation. The embodiment illustrated in FIG. 12 is merely an example. It should be understood that additional instances of the first perforation 132a and/or other deviations between perforation sizes and/or perforations shapes may be included in other embodiments.

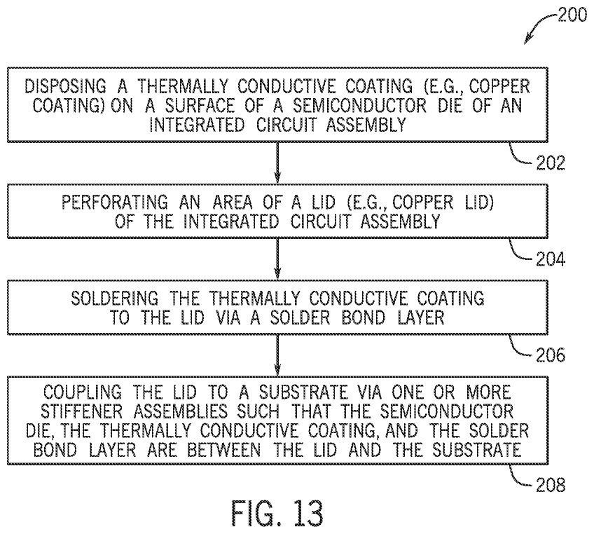

FIG. 13 is a process flow diagram of an embodiment of a method 200 of manufacturing at least a portion of an integrated circuit assembly, including a die (e.g., semiconductor die) coupled to a lid (e.g., copper lid) via a solder bond layer. It should be noted that an ordering of the steps of the method 200 illustrated in FIG. 13 and described in detail below should not be taken to necessarily imply a chronology of the steps of the method 200. Indeed, while the ordering of the steps of the method 200 illustrated in FIG. 13 and described in detail below may be performed chronologically, other suitable orderings and/or chronologies are also possible.

In the illustrated embodiment, the method 200 includes disposing (block 202) a thermally conductive coating (e.g., copper coating) on a surface of the die, such as the surface of a body of the die. The thermally conductive coating may be disposed on the surface of the die via a thin film or vapor deposition technique.

The method 200 also includes perforating (block 204) an area of the lid (e.g., copper lid), although in certain embodiments, the area of the lid may not be perforated. As previously described, the perforations in the area of the lid, where the area is configured to be coupled to a solder bond layer, may enhance structural characteristics of the integrated circuit assembly relative to traditional embodiments. For example, the perforations may permit a certain amount of swelling of the die of the integrated circuit assembly without exerting an undesirable amount of compression against the swelling of the die. In certain embodiments, a solder bond layer, described in greater detail below, may include additional perforations aligned with the perforations in the area of the lid.

The method 200 also includes soldering (block 206) the thermally conductive coating to the lid via a solder bond layer. As previously described, a solder bond material may be disposed between the thermally conductive coating of the die and the lid. The assembly may be heated until the solder bond material melts. While heating the assembly may heat the thermally conductive coating and the lid, the solder bond material may include a lower melting temperature than the thermally conductive coating and the lid. Accordingly, a controlled heating at or just above the melting temperature of the solder bond material will cause the solder bond material to melt while the thermally conductive coating and the lid do not melt. The assembly is allowed to cool until the solder bond material hardens into the solder bond layer coupling the thermally conductive coating of the die with the lid. The method 200 also includes coupling (block 208) the lid to a substrate via one or more stiffener assemblies to at least partially form an enclosure defining a cavity, and such that the die, the thermally conductive coating of the die, and the solder bond layer are positioned in a cavity defined by the enclosure and between the lid and the substrate.

In general, presently disclosed embodiments may improve heat transfer in integrated circuit assemblies (e.g., heat dissipation from a die, such as a semiconductor die, to a lid), improve structural characteristics of the integrated circuit assemblies (e.g., by permitting a controlled swelling of the die without exerting undesirable compression against the swelling of the die), or any combination thereof. Features described in detail above relating to sizes, materials, and/or locations of various componentry of the integrated circuit assemblies may contribute to and/or enhance the heat transfer and structural benefits associated with presently disclosed embodiments.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112 (f). However, for any claims containing elements designated in any other manner, it is intended that such elements are not to be interpreted under 35 U.S.C. 112 (f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. An integrated circuit assembly, comprising:
a semiconductor die;
a copper coating disposed on a surface of the semiconductor die;
a solder bond layer disposed on the copper coating; and
a copper lid disposed on the solder bond layer.

2. The integrated circuit assembly of claim 1, wherein the copper lid comprises a perforated area, and the solder bond layer is disposed between the copper coating and the perforated area.

3. The integrated circuit assembly of claim 2, wherein the solder bond layer comprises an additional perforated area, and perforations of the perforated area are spatially aligned with additional perforations of the additional perforated area.

4. The integrated circuit assembly of claim 1, wherein the solder bond layer comprises a thickness between 10 microns and 100 microns.

5. The integrated circuit assembly of claim 1, wherein a portion of the copper lid spatially aligned with the solder bond layer comprises a thickness between 30 microns and 350 microns.

6. The integrated circuit assembly of claim 1, comprising a substrate coupled to the copper lid via one or more stiffener assemblies, wherein the semiconductor die, the copper coating, and the solder bond layer are disposed between the copper lid and the substrate.

7. An integrated circuit assembly, comprising:
a semiconductor die;
a thermally conductive coating disposed on a surface of the semiconductor die;
a solder bond layer disposed on the thermally conductive coating; and
a lid disposed on the solder bond layer.

8. The integrated circuit assembly of claim 7, wherein the lid comprises a first thermal conductivity greater than 10 Watts per Meter-Kelvin, and the thermally conductive coating comprises a second thermal conductivity greater than 10 Watts per Meter-Kelvin.

9. The integrated circuit assembly of claim 7, wherein the solder bond layer comprises a thermal conductivity greater than 10 Watts per Meter-Kelvin.

10. The integrated circuit assembly of claim 7, wherein the solder bond layer comprises a melting temperature greater than 200 degrees Celsius and less than 350 degrees Celsius.

11. The integrated circuit assembly of claim 7, wherein the lid comprises a perforated area, and the solder bond layer is disposed between the thermally conductive coating and the perforated area.

12. The integrated circuit assembly of claim 11, wherein the perforated area, the solder bond layer, and the thermally conductive coating are spatially aligned with a heat generating element of the semiconductor die.

13. The integrated circuit assembly of claim 12, wherein the heat generating element comprises processing circuitry or dynamic random-access memory (DRAM).

14. The integrated circuit assembly of claim 7, wherein the solder bond layer comprises a thickness of 10 microns to 100 microns.

15. The integrated circuit assembly of claim 7, wherein a portion of the lid spatially aligned with the solder bond layer comprises a thickness between 30 microns and 350 microns.

16. The integrated circuit assembly of claim 7, comprising a substrate coupled to the lid via one or more stiffener assemblies, wherein the semiconductor die, the thermally conductive coating, and the solder bond layer are disposed between the lid and the substrate.

17. A method for manufacturing an integrated circuit assembly, comprising:
disposing a thermally conductive coating on a surface of a semiconductor die of the integrated circuit assembly; and
soldering the thermally conductive coating to a lid of the integrated circuit assembly via a solder bond layer.

18. The method of claim 17, wherein the lid includes an area having perforations therein, and the method comprises soldering the thermally conductive coating to the area of the lid via the solder bond layer.

19. The method of claim 17, comprising coupling the lid to a substrate via one or more stiffener assemblies such that the semiconductor die, the thermally conductive coating, and the solder bond layer are between the lid and the substrate.

20. The method of claim 17, wherein the thermally conductive coating is a copper coating, and the lid is a copper lid.
